(19) United States
(12) Patent Application Publication
(10) Pub. No.: US 2013/0249543 A1
(43) Pub. Date: Sep. 26, 2013

(54) Correction Circuit for Output Duty of Hall Element, Hall Sensor and Method of Correcting Output Duty of Hall Element

(71) Applicant: SAMSUNG ELECTRO-MECHANICS CO., LTD, Suwon-si (KR)

(72) Inventor: Soo Woong Lee, Suwon-si (KR)

(73) Assignee: SAMSUNG ELECTRO-MECHANICS CO., LTD, Suwon-si (KR)

(21) Appl. No.: 13/797,936

(22) Filed: Mar. 12, 2013

(30) Foreign Application Priority Data
Mar. 20, 2012 (KR) 10-2012-0028315

(51) Int. Cl. H03K 5/156

(52) U.S. Cl. CPC H03K 5/1565
USPC 324/251; 327/175

(57) ABSTRACT

Disclosed herein are a correction circuit for output duty of a Hall element, a Hall sensor, and a method of correcting the output duty of the Hall element. According to an exemplary embodiment of the present invention, the correction circuit includes an amplification and output unit for amplifying an output of the Hall element and outputting a sqaure wave signal; a duty detection unit for detecting a duty ratio of the sqaure wave signal output by the amplification and output unit; and a duty correction unit for applying a feedback correction signal to the amplification and output unit accoring to the detected duty ratio.

### CROSS REFERENCE(S) TO RELATED APPLICATIONS

This application claims the benefit under 35 U.S.C. Section 119 of Korean Patent Application Serial No. 10-2012-0028315, entitled “Correction Circuit for Output Duty of Hall Element, Hall Sensor, and Method of Correcting Output Duty of Hall Element” filed on Mar. 20, 2012, which is hereby incorporated by reference in its entirety into this application.

### BACKGROUND OF THE INVENTION

1. Technical Field

The present invention relates to a correction circuit for output duty of a Hall element, a Hall sensor, and a method of correcting the output duty of the Hall element, and more particularly, to a correction circuit for output duty of a Hall element that detects duty of a square wave output of the Hall element and corrects feedback, a hall sensor, and a method of correcting the output duty of the Hall element.

2. Description of the Related Art

A motor driving circuit for driving a motor needs to detect location information of an electromagnet used in the motor. To this end, a Hall sensor or a Hall element for detecting magnetic field information of the electromagnet is used. The Hall element having a Wheatstone bridge structure outputs a signal of several μV and several hundreds of mV/mT according to a component of a semiconductor material. Such a signal is very small to determine whether a magnetic field is present, the signal must be amplified to a sufficiently large signal through a Hall amplifier. In this regard, the Hall amplifier, more specifically, a Schmitt trigger circuit of the Hall amplifier, exhibits hysteresis characteristics to output a low or high signal as shown in FIG. 2A.

It is very important to uniformly maintain a 50:50 duty cycle with respect to the Hall amplifier or the Schmitt trigger circuit that outputs a low or high signal. This is because the motor can be driven at a uniform speed in a case of the 50:50 duty cycle. However, it is not easy to maintain the 50:50 duty cycle of the Hall amplifier or the Schmitt trigger circuit. This is because an output of a weak level of the Hall element or noise added to the Hall amplifier may deteriorate the duty cycle of the Hall amplifier.

FIG. 2A is a signal flow graph of a Hall amplifier having hysteresis in a general structure. FIG. 6A is a graph of a simulation result of a conventional system before a correction circuit for output duty of a Hall element according to the present invention is applied.

In FIG. 2A, if the Hall element outputs a weak voltage signal with respect to a magnetic field signal, a Schmitt trigger circuit outputs a square wave signal that is converted into digital after being amplified to analog. The hysteresis of the Hall element increases in proportional to a gain of the Hall amplifier during the analog amplification. The Schmitt trigger circuit sets a hysteresis section by using +/− delta voltages with respect to a common mode voltage. If the + delta voltage is set as an operate point (OP) voltage, and the − delta voltage is set as an release point (RP) voltage, as shown in FIGS. 2A and 6A, the Schmitt trigger circuit does not react between the OP voltage and the RP voltage, outputs a low signal instantly when an output signal exceeds the OP voltage, and outputs a high signal instantly when the output signal falls below the RP voltage. In this regard, although the signal flow shown in FIG. 2A has no problem in maintaining a duty ratio in a less noisy system, a problem shown in FIG. 6A occurs in a more noisy environment. That is, a noisy signal or environment is provided in FIG. 6A before the correction circuit for output duty of the Hall element according to the present invention is applied.

As shown in FIG. 6A, the output signal of the Hall element has noise exceeding a certain level. Thus, the output signal of the Schmitt trigger circuit having hystresis cannot maintain a 50:50 duty cycle. In FIG. 6A, the Hall element operates at 10 kHz, in which a cycle is 100 μS, and thus the output signal having no noise has 50 μS:50 μS. However, as shown in FIG. 6A, a high or low section of the output signal has 42.31 μS, 57.06 μS due to influence of noise, even a Glitch signal is also output.

### RELATED ART DOCUMENTS

### Patent Documents

(Patent Document 1) Japanese Patent Laid-Open Publication No. 2002-315384 (laid-open published on Oct. 25, 2002)

(Patent Publication 2) U.S. Patent Laid-Open Publication No. 2009/0153084 (laid-open published on Jun. 18, 2009)

### SUMMARY OF THE INVENTION

An object of the present invention is to provide a technology of maintaining an optimal state of a duty cycle always by correcting feedback through a correction circuit in a case where the duty cycle of a square wave signal having a converted output of a Hall element due to noise deteriorates. That is, the object of the present invention is to solve a problem of deterioration of a duty ratio due to noise that occurs in an output of the Hall element.

According to an exemplary embodiment of the present invention, there is provided a correction circuit for output duty of a Hall element, the correction circit including: an amplification and output unit for amplifying an output of the Hall element and outputting a sqaure wave signal; a duty detection unit for detecting a duty ratio of the sqaure wave signal output by the amplification and output unit; and a duty correction unit for applying a feedback correction signal to the amplification and output unit accoring to the detected duty ratio.

The duty detection unit may calculate the duty ratio by counting high sections and low sections according to previously set clocks during one cycle of the square wave signal.

The duty correction unit may include: a state machine for generating a duty ratio correction bit according to the duty ratio detected by the duty detection unit; and a hysteresis section control unit for feeding back and controlling a width of a hysteresis section for outputting the square wave signal, according to the duty ratio correction bit generated by the state machine.

The state machine may generate a correction bit corresponding to a middle of a correctable bit range according to a size comparison of a high section and a low section of the detected duty ratio.

The state machine may generate the correction bit in a step-down or step-up manner within a correctable bit range according to the detected duty ratio.

The state machine may calculate a correction bit corresponding to a ratio of a high section and a low section of the detected duty ratio from a previously stored table.

According to another exemplary embodiment of the present invention, there is provided a Hall sensor including: a Hall element for outputting a voltag signal according to an approaching magnetic field signal; an amplification unit for analog-amplifying an output of the Hall element; a Shumitt trigger circuit for generating a sqaure wave signal from an output of the amplification unit according to a hysteresis section; a duty detection unit for detecting a duty ratio of the sqaure wave signal output by the Shumitt trigger circuit; and a duty correction unit for applying a feedback correction signal to the Shumitt trigger circuit accoring to the detected duty ratio.

The duty correction unit may include: a state machine for generating a duty ratio correction bit according to the duty ratio detected by the duty detection unit; and a hysteresis section control unit for feeding back and controlling a width of the hysteresis section according to the duty ratio correction bit generated by the state machine.

The state machine may generate a correction bit corresponding to a middle of a correctable bit range according to a size comparison of a high section and a low section of the detected duty ratio.

The state machine may generate the correction bit in a step-down or step-up manner within a correctable bit range according to the detected duty ratio.

The state machine may calculate a correction bit corresponding to a ratio of a high section and a low section of the detected duty ratio from a previously stored table.

According to another exemplary embodiment of the present invention, there is provided a method of correcting output duty of a Hall element, the method including: an amplification and output operation of amplifying an output of the Hall element and outputting a sqaure wave signal; a duty detection oepration of detecting a duty ratio of the sqaure wave signal output in the amplification and output operation; and a duty correction operation of applying a duty ratio correction signal to the amplification and output operation accoring to the detected duty ratio.

The duty correction operation may include: a correction bit generation operation of generating a duty ratio correction bit according to the duty ratio detected in the duty detection operation; and a feedback correction operation of applying a feedback signal for controlling a width of a hysteresis section, according to the generated duty ratio correction bit, to the amplification and output operation.

The correction bit generation operation may generate a correction bit corresponding to a middle of a correctable bit range according to a size comparison of a high section and a low section of the detected duty ratio.

The correction bit generation operation may generate the correction bit in a step-down or step-up manner within a correctable bit range according to the detected duty ratio.

The correction bit generation operation may calculate a correction bit corresponding to a ratio of a high section and a low section of the detected duty ratio from a previously stored table.

The duty detection operation may calculate the duty ratio by counting high sections and low sections according to previously set clocks during one cycle of the square wave signal.

The amplification and output operation may include: an amplification operation of analog-amplifying the output of the Hall element; and a sqaure wave signal output operation of generating a sqaure wave signal from an output of the amplification operation according to the hysteresis section.

### BRIEF DESCRIPTION OF THE DRAWINGS

FIG. 1 is a block diagram schematically of a correction circuit for output duty of a Hall element according to an embodiment of the present invention;

FIG. 2A is a signal flow graph of a Hall sensor, and FIG. 2B is a schematic diagram for describing a duty calculation method according to an example of the present invention;

FIG. 3 is a block diagram schematically of a correction circuit for output duty of a Hall element and a Hall sensor according to another embodiment of the present invention;

FIG. 4 is a diagram for describing a correction bit generation method of a state machine according to an example of the present invention;

FIG. 5 is a diagram of a hystresis range for each correction bit according to an example of the present invention;

FIG. 6A is a graph of a simulation result before a correction circuit for output duty of a Hall element according to an example of the present invention is applied, and FIG. 6B is a graph of a simulation result after a correction circuit for output duty of a Hall element according to an example of the present invention is applied;

FIG. 7 is a flowchart schematically of a method of correcting output duty of a Hall element according to an embodiment of the present invention; and

FIG. 8 is a flowchart schematically of a method of correcting output duty of a Hall element according to another embodiment of the present invention.

### DESCRIPTION OF THE PREFERRED EMBODIMENTS

Exemplary embodiments of the present invention for accomplishing the above-mentioned objects will be described with reference to the accompanying drawings. In describing exemplary embodiments of the present invention, the same reference numerals will be used to describe the same components and an additional description that is overlapped or allow the meaning of the present invention to be restrictively interpreted will be omitted.

In the specification, it will be understood that unless a term such as ‘directly’ is not used in a connection, coupling, or disposition relationship between one component and another component, one component may be ‘directly connected to’, ‘directly coupled to’ or ‘directly disposed to’ another element or be connected to, coupled to, or disposed to another element, having the other element intervening therebetween. In addition, this may also be applied to terms including the meaning of contact such as ‘on’, ‘above’, ‘below’, ‘under’, or the like. In the case in which a standard element is upset or is changed in a direction, terms related to a direction may be interpreted to including a relative direction concept.

Although a singular form is used in the present description, it may include a plural form as long as it is opposite to the concept of the present invention and is not contradictory in view of interpretation or is used as clearly different meaning. It should be understood that “include”, “have”, “comprise”, “be configured to include”, and the like, used in the present description do not exclude presence or addition of one or more other characteristic, component, or a combination thereof.

A correction circuit for output duty of a Hall element according to a first embodiment of the present invention will be described with reference to the drawings. In this regard, reference numerals that are not shown in the referring drawings may be those of other drawings that show the same construction.

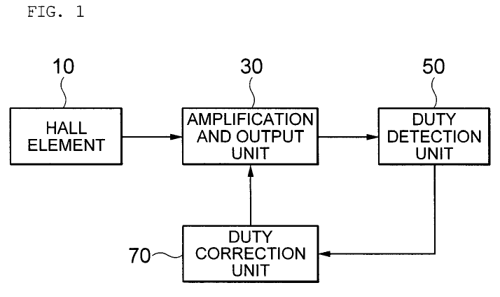

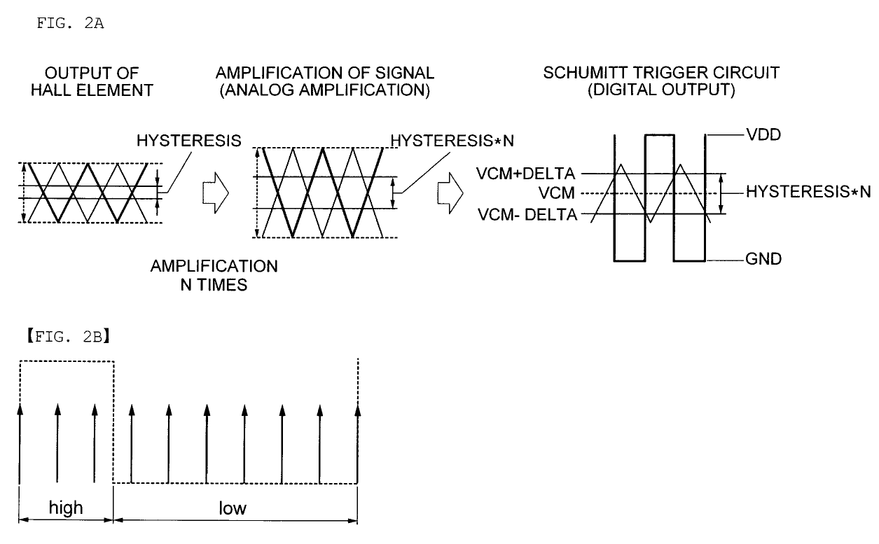

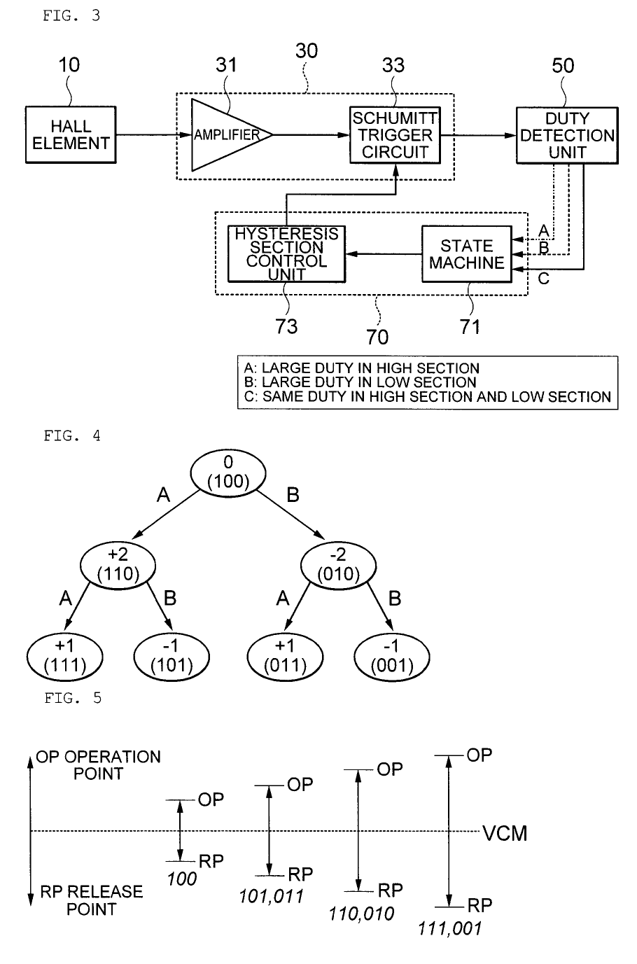

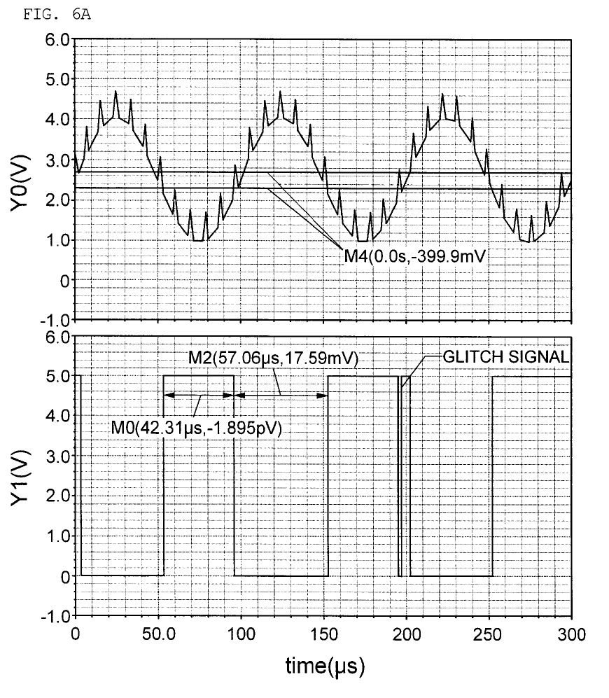

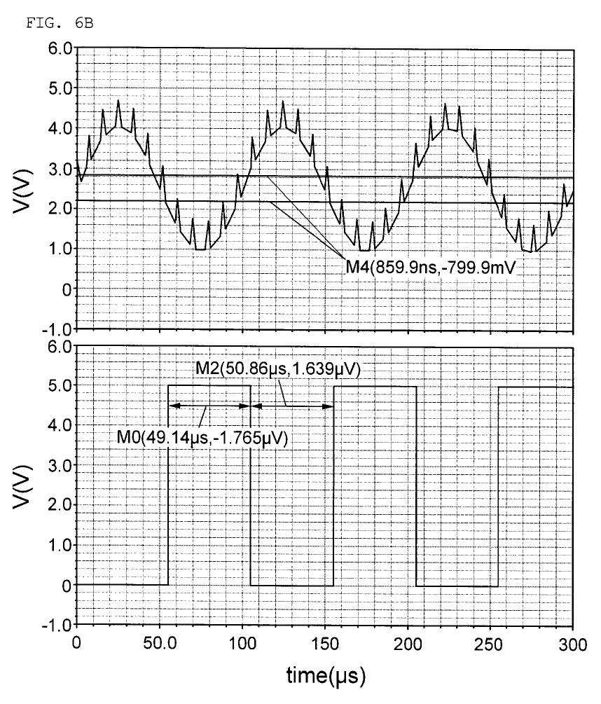

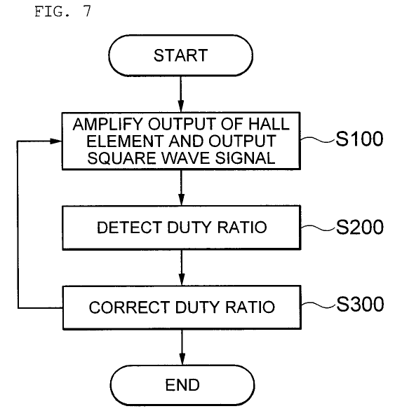

FIG. 1 is a block diagram schematically of a correction circuit for output duty of a Hall element according to an embodiment of the present invention. FIG. 2A is a signal flow graph of a Hall sensor. FIG. 2B is a schematic diagram for describing a duty calculation method according to an example of the present invention. FIG. 3 is a block diagram schematically of a correction circuit for output duty of a Hall element and a Hall sensor according to another embodiment of the present invention. FIG. 4 is a diagram for describing a correction bit generation method of a state machine according to an example of the present invention. FIG. 5 is a diagram of a hystresis range for each correction bit according to an example of the present invention. FIG. 6A is a graph of a simulation result before a correction circuit for output duty of a Hall element according to an example of the present invention is applied. FIG. 6B is a graph of a simulation result after a correction circuit for output duty of a Hall element according to an example of the present invention is applied.

A Hall element 10 shown in FIGS. 1 and 3 may not be included in elements of a correction circuit for output duty of the Hall element 10 according to a first embodiment of the present invention but is illustrated for the understanding of the present invention.

Referring to FIG. 1, the correction circuit for output duty of the Hall element 10 according to the present embodiment may include an amplification and output unit 30, a duty detection unit 50, and a duty correction unit 70.

The amplification and output unit 30 of FIG. 1 amplifies an output of the Hall element 10 and outputs a square wave signal from an amplified signal. The Hall element 10 outputs a voltage signal according to an approaching magnetic field signal. In this regard, the voltage signal of the Hall element 10 is weak, and thus the voltage signal needs to be sufficiently amplified in order to determine magnetic field information included in the output voltage signal. Thus, the output voltage signal is amplified by the amplification and output unit 30. Also, the amplified signal is output after being converted into the square wave signal. An analog amplification of the output signal of the Hall element 10 may be performed by, for example, a differential amplifier 31 of FIG. 3. Also, the amplified signal may be output as the square wave signal through a Schmitt trigger circuit 33 of FIG. 3. Referring to FIG. 2A, an output of the Hall element 10 may be amplified N times through the analog amplification process in which hysteresis is amplified N times. Referring to FIG. 2A, with respect to an operation point (OP) (VCM+delta) and a release point (RP) (VCM−delta) of a hysteresis section, the amplified signal is changed to a low section at the OP when rising, rises and then falls, and then is changed to a high section at the RP. That is, if the amplified signal falls below the RP, a high signal is output, and, if the amplified signal rises above the OP, a low signal is output. A digital output signal does not change between the OP and the RP, i.e. in the hysteresis section. Thus, the square wave signal may be obtained. The square wave signal is shown in FIG. 2B which shows an example of a different duty ratio of the high section and the low section.

Next, the duty detection unit 50 of FIG. 1 detects a duty ratio of the square wave signal output by the amplification and output unit 30.

Referring to FIG. 2B, according to an example, the duty detection unit 50 may calculate the duty ratio by counting high sections and low sections according to previously set clocks during one cycle of the square wave signal. In this regard, a clock for counting high sections and low sections must have a high frequency enough to calculate the duty ratio of each section. In FIG. 2B, the number of clocks of high sections is 3, and the number of clocks of low sections is 7, and thus the duty ratio may be 30:70.

Next, the duty correction unit 70 of FIG. 1 applies a feedback correction signal to the amplification and output unit 30 according to the duty ratio detected by the duty detection unit 50.

Referring to FIG. 3, according to an example, the duty correction unit 70 may include a state machine 71 and a hysteresis section control unit 73.

In FIG. 3, the state machine 71 generates a duty ratio correction bit according to the duty ratio detected by the duty detection unit 50. A width of, for example, the hysteresis section is corrected according to the duty ratio correction bit generated by the state machine 71, and thus the Schumitt trigger circuit 33 of FIG. 3 may correct the duty ratio of the square wave signal.

In this regard, according to an example with reference to FIG. 4, the state machine 71 may generate a correction bit corresponding to a middle of a correctable bit range according to a size comparison of a high section and a low section of the detected duty ratio. FIG. 4 is a diagram for describing a method of generating the correction bit of the state machine 71 according to an example of the present invention. In this regard, the correction bit corresponding to the middle of the correctable bit range may be generated.

For example, it is assumed that the duty ratio of the high section and the low section is 30:70 as shown in FIG. 2B, and the correction bit is 3 bits as shown in FIG. 4. In this case, since the low section is greater than the high section, the state machine 71 of FIG. 3 receives a duty ratio detection result as a case Continuously, referring to FIG. 4, in a case of “B”, since the low section is great, a correction is possible to reduce the low section. In this regard, a correction bit for reducing the low section can be 011, 010, and 001 that are smaller than 100 indicating a reference bit state and may be corrected to a bit state 010 that is the correction bit corresponding to the middle of the correctable bit range. The bit corrected to the bit 010 increases the width of the hysteresis section of the Shumitt trigger circuit 33 as shown in FIG. 5, and thus the duty ratio of the square wave signal is repeatedly calculated. As a result of repeatedly calculating the duty ratio, if the duty ratio of the high section and the low section is 60:40, the state machine 71 of FIG. 3 receives a case “A”, and the state machine 71 of FIG. 4 generates a bit state 011 that is a correction bit increased in a direction “A” in the bit state 010. Finally, the duty correction bit makes it possible to maintain a value closer to the duty ratio of 50:50 as much as possible through continuous feedback in this manner. FIG. 4 shows a case where the correction bit is 3 bits. The more the bit and state increase, the closer to the duty ratio of 50:50 the tuning can be more elaborately performed.

Although not shown, according to another example, unlike shown in FIG. 4, the state machine 71 may generate a correction bit in a step-down or step-up manner within a correctable bit range according to a detected duty ratio. That is, in FIG. 4, the correction bit may be generated by sequentially stepping down a maximum bit state to a small bit state or sequentially stepping up in a minimum bit state within the correctable bit range. For example, as shown in FIG. 2B, in a case where a duty ratio of a high section and a low section is 30:70, and the correction bit is 3 bits, the correction bit must be corrected in a direction to which the low section is reduced, for example, in a direction “B” of FIG. 4, and a correctable bit state can be 011, 010, and 001 in a bit state 100. In the step down method, the correction bit is sequentially changed from the bit state 011 to the bit state 001. In the step up method, the correction bit is sequentially changed from the bit state 001 to the bit state 011. Thus, the correction bit may be fedback to maintain the duty ratio closer to 50:50.

Further, although not shown, according to another example, the state machine 71 may calculate a correction bit corresponding to a ratio of a high section and a low section of a detected duty ratio from a previously stored table.

The hysteresis section control unit 73 of FIG. 3 feedbacks and controls the width of the hysteresis section for outputting the square wave signal, according to the duty ratio correction bit generated by the state machine 71. Referring to FIG. 5, a change in the correction bit generated by the state machine 71 may cause a change in a DC level of the hysteresis section in which the Shumitt trigger circuit 33 operates, i.e. the OP and the RP. If the correction bit 100 is an initial value in FIG. 5, a value closer to 100 is a case of small hysteresis. In other words, since OP/RP is set with respect to a voltage common mode (VCM), the value closer to 100 is a case of a small difference between OP/RP. The farther from the bit state 100 the correction bit, the greater the value of hysteresis. FIG. 5 is a diagram of a hystresis range for each correction bit of the state machine 71 of FIG. 4.

FIG. 6B shows a simulation result of a system to which the correction circuit for output duty of the Hall element 10 according to the present embodiment is applied. According to the simulation result of the system to which the correction circuit for output duty of the Hall element 10 as shown in FIG. 6B, a duty ratio is improved to 49:51 of FIG. 6B from 43:57 of FIG. 6A to which the correction circuit is not applied. The simulation result of FIG. 6B shows that the correction bit of the state machine 71 of FIGS. 3 and 4 is 3 bits. As described above, to correct the duty ratio more clearly, tuning can be more elaborately performed by allocating an additional correction bit.

Next, a second embodiment of the present invention is now described with reference to FIG. 3. In this regard, correction circuits for output duty of the Hall element 10 according to the first embodiment of the present invention and FIGS. 1, 2B, 4, 5, and 6B as well as FIG. 3 may be referred, and thus redundant descriptions may be omitted.

FIG. 3 is a block diagram schematically of a Hall sensor according to another embodiment of the present invention.

Referring to FIG. 3, the Hall sensor according to an example may include the Hall element 10, the amplifier 31, the Shumitt trigger circuit 33, the duty detection unit 50, and the duty correction unit 70.

In this regard, the Hall element 10 outputs a voltage signal according to an approaching magnetic field signal.

The amplification unit 31 of FIG. 3 analog-amplifies the output of the Hall element 10. The amplification unit 31 may be a differential amplifier. In FIG. 2A, the output of the Hall element 10 is analog-amplified N times.

Next, the Schumitt trigger circuit 33 of FIG. 3 generates the square wave signal from the output of the amplifier 31 according to the hysteresis section. In FIG. 2A, an analog amplification signal is output as the square wave signal through the Schumitt trigger circuit 33 according to the hysteresis section.

Next, the duty detection unit 50 of FIG. 3 detects a duty ratio of the square wave signal output by the Schumitt trigger circuit 33. Referring to FIG. 2B, according to an example, the duty detection unit 50 may calculate the duty ratio by counting high sections and low sections according to the previously set clock during one cycle of the square wave signal.

Next, the duty correction unit 70 applies a feedback correction signal to the Schumitt trigger circuit 33 according to the duty ratio detected by the duty detection unit 50.

More specifically, referring to FIG. 3, according to an example, the duty correction unit 70 may include the state machine 71 and the hysteresis section control unit 73. In this regard, the state machine 71 of FIG. 3 may generate the duty ratio correction bit according to the duty ratio detected by the duty detection unit 50.

Furthermore, referring to FIG. 4, according to an example, the state machine 71 generates a duty ratio correction bit according to the duty ratio detected by the duty detection unit 50. The state machine may generate a correction bit corresponding to a middle of a correctable bit range according to a size comparison of a high section and a low section of the detected duty ratio.

Although not shown, according to another example, the state machine 71 may generate a correction bit in a step-down or step-up manner within a correctable bit range according to a detected duty ratio.

Further, although not shown, according to another example, the state machine 71 may calculate a correction bit corresponding to a ratio of a high section and a low section of a detected duty ratio from a previously stored table.

Continuously, the hysteresis section control unit 73 of FIG. 3 may feedback and control a width of the hysteresis section according to the duty ratio correction bit generated by the state machine 71.

Next, a method of correcting output duty of a Hall element according to a third embodiment of the present invention will be described in detail. In this regard, correction circuits for output duty of the Hall element 10 according to the first embodiment of the present invention, the Hall sensors according to the second embodiment of the present invention, and FIGS. 1, 2B, 3, 4, 5, and 6B may be referred, and thus redundant descriptions may be omitted.

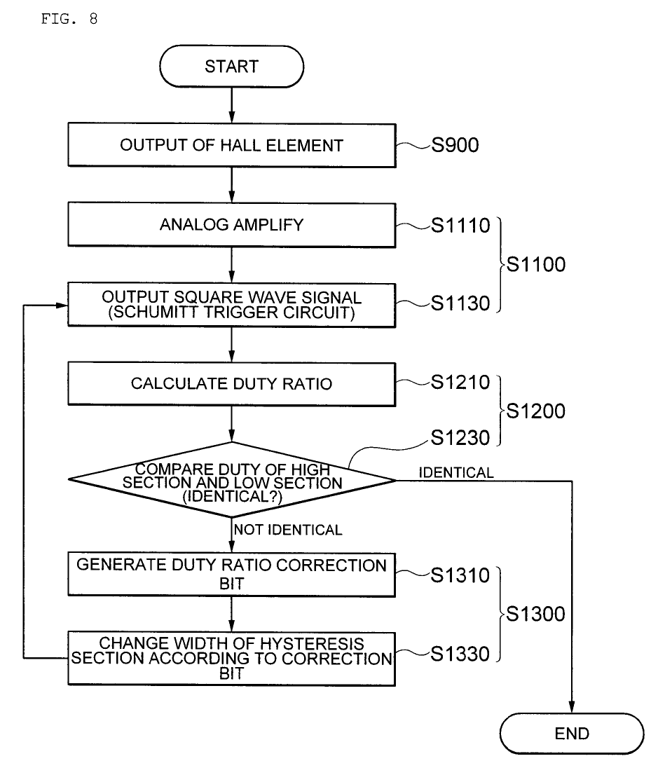

FIG. 7 is a flowchart schematically of a method of correcting output duty of the Hall element 10 according to an embodiment of the present invention, and FIG. 8 is a flowchart schematically of a method of correcting output duty of the Hall element 10 according to another embodiment of the present invention.

Referring to FIG. 7, the method of correcting output duty of the Hall element 10 according to an example may include an amplification and output operation (S100), a duty detection operation (S200), and a duty correction operation (S300).

In the amplification and output operation (S100) of FIG. 7, an output of the Hall element 10 is amplified, and an amplified signal is output as a square wave signal. Referring to FIG. 8, before the amplification and output operation (S1100), the Hall element 10 outputs a voltage signal according to an approaching magnetic field signal (S900).

In this regard, referring to FIG. 8, according to an example, an amplification and output operation (S1100) may include an amplification operation (S1110) of receiving an output of the Hall element 10 and analog-amplifying the output and a square wave signal output operation (S1130) of the Shumitt trigger circuit 33 of generating and outputting a square wave signal from the output signal analog-amplified in the amplification operation (S1110) according to a hysteresis section. In this regard, the amplification operation (S1110) may be performed by, for example, the differential amplifier 31.

Next, in the duty detection operation (S200) of FIG. 7, a duty ratio of the square wave signal output in the amplification and output operation (S100) is detected.

In this regard, referring to FIG. 2B and/or FIG. 8, according to an example, in a duty detection operation (S1200), the duty ratio may be calculated by counting high sections and low sections according to a previously set clock during one cycle of the square wave signal (S1210, S1230).

Next, in the duty correction operation (S300) of FIG. 7, a duty correction signal is fedback and applied to the amplification and output operation (S100) according to the duty ratio detected in the duty detection operation (S200).

In this regard, this will be described in more detail with reference to FIG. 8. Referring to FIG. 8, a duty correction operation (S1300) may include a correction bit generation operation (S1310) and a feedback correction operation (S1330).

In the correction bit generation operation (S1310) of FIG. 8, a duty ratio correction bit is generated according to the duty ratio detected in the duty detection operation (S1200).

In this regard, referring to FIG. 4, according to an example, in the correction bit generation operation (S1310), a correction bit corresponding to a middle of a correctable bit range may be generated according to a size comparison of a high section and a low section of the detected duty ratio.

Alternatively, although not shown, according to another example, in the correction bit generation operation (S1310), a correction bit may be generated in a step-down or step-up manner within a correctable bit range according to a detected duty ratio.

Although not shown, according to another example, in the correction bit generation operation (S1310), a correction bit corresponding to a ratio of a high section and a low section of a detected duty ratio may be calculated from a previously stored table.

Further, in the feedback correction operation (S1330) of FIG. 8, a feedback signal for controlling a width of a hysteresis section according to the duty ratio correction bit generated in the correction bit generation operation (S1310) may be applied to the amplification and output operation (S1100), more specifically, to the square wave signal output operation (S1130).

As described above, in a case where a duty cycle of a square wave signal having a converted output of a Hall element due to noise deteriorates, such a deterioration of the duty cycle is fedback and corrected through a correction circuit, thereby maintaining an optimal state of the duty cycle all the time.

That is, a problem of deterioration of the duty ratio due to noise that occurs in an output of a Hall element can be solved.

Further, accordingly, as an applicable example, the optimal state of the duty cycle is maintained all the time, a rotational speed of a motor can be uniformly maintained.

It is obvious that various effects directly stated according to various exemplary embodiment of the present invention may be derived by those skilled in the art from various configurations according to the exemplary embodiments of the present invention.

The accompanying drawings and the above-mentioned exemplary embodiments have been illustratively provided in order to assist in understanding of those skilled in the art to which the present invention pertains. In addition, the exemplary embodiments according to various combinations of the aforementioned configurations may be obviously implemented by those skilled in the art from the aforementioned detailed explanations. Therefore, various exemplary embodiments of the present invention may be implemented in modified forms without departing from an essential feature of the present invention. In addition, a scope of the present invention should be interpreted according to claims and includes various modifications, alterations, and equivalences made by those skilled in the art.

What is claimed is:

1. A correction circuit for output duty of a Hall element, the correction circit comprising:
an amplification and output unit for amplifying an output of the Hall element and outputting a sqaure wave signal;
a duty detection unit for detecting a duty ratio of the sqaure wave signal output by the amplification and output unit; and
a duty correction unit for applying a feedback correction signal to the amplification and output unit accoring to the detected duty ratio.

2. The correction circit according to claim 1, wherein the duty detection unit calculates the duty ratio by counting high sections and low sections according to previously set clocks during one cycle of the square wave signal.

3. The correction circit according to claim 1, wherein the duty correction unit includes:
a state machine for generating a duty ratio correction bit according to the duty ratio detected by the duty detection unit; and
a hysteresis section control unit for feeding back and controlling a width of a hysteresis section for outputting the square wave signal, according to the duty ratio correction bit generated by the state machine.

4. The correction circit according to claim 2, wherein the duty correction unit includes:
a state machine for generating a duty ratio correction bit according to the duty ratio detected by the duty detection unit; and
a hysteresis section control unit for feeding back and controlling a width of a hysteresis section for outputting the square wave signal, according to the duty ratio correction bit generated by the state machine.

5. The correction circit according to claim 3, wherein the state machine generates a correction bit corresponding to a middle of a correctable bit range according to a size comparison of a high section and a low section of the detected duty ratio.

6. The correction circit according to claim 3, wherein the state machine generates the correction bit in a step-down or step-up manner within a correctable bit range according to the detected duty ratio.

7. The correction circit according to claim 3, wherein the state machine calculates a correction bit corresponding to a ratio of a high section and a low section of the detected duty ratio from a previously stored table.

8. A Hall sensor comprising:
a Hall element for outputting a voltag signal according to an approaching magnetic field signal;
an amplification unit for analog-amplifying an output of the Hall element;
a Shumitt trigger circuit for generating a sqaure wave signal from an output of the amplification unit according to a hysteresis section;
a duty detection unit for detecting a duty ratio of the sqaure wave signal output by the Shumitt trigger circuit; and
a duty correction unit for applying a feedback correction signal to the Shumitt trigger circuit accoring to the detected duty ratio.

9. The Hall sensor according to claim 8, wherein the duty correction unit includes:
a state machine for generating a duty ratio correction bit according to the duty ratio detected by the duty detection unit; and
a hysteresis section control unit for feeding back and controlling a width of the hysteresis section according to the duty ratio correction bit generated by the state machine.

10. The Hall sensor according to claim 9, wherein the state machine generates a correction bit corresponding to a middle of a correctable bit range according to a size comparison of a high section and a low section of the detected duty ratio.

11. The Hall sensor according to claim 9, wherein the state machine generates the correction bit in a step-down or step-up manner within a correctable bit range according to the detected duty ratio.

12. The Hall sensor according to claim 9, wherein the state machine calculates a correction bit corresponding to a ratio of a high section and a low section of the detected duty ratio from a previously stored table.

13. A method of correcting output duty of a Hall element, the method comprising:
an amplification and output operation of amplifying an output of the Hall element and outputting a sqaure wave signal;
a duty detection oepration of detecting a duty ratio of the sqaure wave signal output in the amplification and output operation; and
a duty correction operation of applying a duty ratio correction signal to the amplification and output operation accoring to the detected duty ratio.

14. The method according to claim 13, wherein the duty correction operation includes:
a correction bit generation operation of generating a duty ratio correction bit according to the duty ratio detected in the duty detection operation; and
a feedback correction operation of applying a feedback signal for controlling a width of a hysteresis section, according to the generated duty ratio correction bit, to the amplification and output operation.

15. The method according to claim 14, wherein the correction bit generation operation generates a correction bit corresponding to a middle of a correctable bit range according to a size comparison of a high section and a low section of the detected duty ratio.

16. The method according to claim 14, wherein the correction bit generation operation generates the correction bit in a step-down or step-up manner within a correctable bit range according to the detected duty ratio.

17. The method according to claim 14, wherein the correction bit generation operation calculates a correction bit corresponding to a ratio of a high section and a low section of the detected duty ratio from a previously stored table.

18. The method according to claim 13, wherein the duty detection operation calculates the duty ratio by counting high sections and low sections according to previously set clocks during one cycle of the square wave signal.

19. The method according to claim 14, wherein the duty detection operation calculates the duty ratio by counting high sections and low sections according to previously set clocks during one cycle of the square wave signal.

20. The method according to claim 13, wherein the amplification and output operation includes:
an amplification operation of analog-amplifying the output of the Hall element; and
a sqaure wave signal output operation of generating a sqaure wave signal from an output of the amplification operation according to the hysteresis section.
